(19) United States
(12) Patent Application Publication
(10) Pub. No.: US 2013/0217316 A1
(43) Pub. Date: Aug. 22, 2013

(54) ENCLOSURE FOR HOUSING ELECTRICAL EQUIPMENT

(71) Applicant: ABB OY, (US)

(72) Inventor: Risto LAURILA, Espoo (FI)

(73) Assignee: ABB OY, Helsinki (FI)

(21) Appl. No.: 13/762,815

(22) Filed: Feb. 8, 2013

(30) Foreign Application Priority Data
Feb. 17, 2012 (EP) 12155878.7

(51) Int. Cl. H05K 5/02

(52) U.S. Cl. CPC H05K 5/0213
USPC 454/184

(57) ABSTRACT

An enclosure for housing electrical equipment includes a bottom part, a wall part and a roof part. The bottom part, the wall part and the roof part define an interior chamber for housing the electrical equipment. The wall part includes at least one first air channel connected to the interior chamber, and the enclosure includes at least one fan for circulating air from inside the interior chamber through the at least one first air channel. The bottom part includes at least one second air channel connected to the interior chamber, and the enclosure includes at least one fan for circulating the air from inside the interior chamber through the at least one second air channel.

### RELATED APPLICATION

This application claims priority under 35 U.S.C. §119 to European Patent Application No. 12144878.7 filed in Europe on Feb. 17, 2012, the entire content of which is hereby incorporated by reference in its entirety.

### FIELD

The present disclosure relates to an enclosure for housing electrical equipment.

### BACKGROUND INFORMATION

Electrical equipment, such as electrical power equipment and/or electronic equipment, which is placed, for example, outdoors may need to be protected from adverse conditions. Such protection can be accomplished with a suitable enclosure around the electrical equipment. An example of an enclosure for electrical equipment is a container-type solution which can be easily transported.

The regulation of heat, including removal of waste heat from the electrical equipment, in such enclosures may be based on circulating air from outside the enclosure through the enclosure to cool down the electrical equipment in the enclosure. The air from outside the enclosure may require filtering, which may in turn require a large filter area or volume and/or cause a significant pressure loss to fans which circulate the air. The energy consumption of the fans may be significant thus deteriorating the overall efficiency of the equipment. In addition, replacement of the filters causes extra costs. The use of outside air may cause further problems because the outside air may contain moisture which may then condensate inside the enclosure and possibly cause corrosion or a short circuit. Further, if the outside air is too cold, it may pose a problem to heat regulation as some equipment may not be functional at low temperatures.

Another alternative for heat regulation in an enclosure for electrical equipment is to use various heat exchangers for transferring waste heat from the equipment inside the enclosure to the outside of the enclosure and thus to isolate the air inside the enclosure from the air outside the enclosure. Such heat exchangers may be bulky and require a lot of space inside the enclosure while available space may be limited.

GB 2284659, WO 01/80615, WO 97/47167 and U.S. Pat. No. 5,467,250 disclose solutions in which a heat exchanger has been mounted in a wall or door of the enclosure for electrical equipment. Such solutions may reduce the space required by the heat exchanger inside the enclosure. A possible problem with these solutions is that the heat regulating capacity of such a wall- or door-mounted heat exchanger may not be sufficient depending on the conditions inside and outside of the enclosure.

### SUMMARY

An exemplary embodiment of the present disclosure provides an enclosure for housing electrical equipment. The exemplary enclosure includes a bottom part, a wall part, and a roof part. The bottom part, the wall part and the roof part define an interior chamber for housing the electrical equipment. The wall part includes at least one first air channel connected to the interior chamber. The bottom part includes at least one second air channel connected to the interior chamber. The enclosure also includes at least one fan configured to circulate air from inside the interior chamber through the at least one first air channel, and the at least one fan may be configured to circulate the air from inside the interior chamber through the at least one second air channel. In addition, the exemplary enclosure includes, inside the interior chamber, at least one cabinet for the electrical equipment. The at least one first air channel is connected to the at least one cabinet at a connection point such that the air circulated from inside the interior chamber through the at least one first air channel enters the at least one first air channel through the at least one cabinet. The connection point of the at least one first air channel and the at least one cabinet includes a first regulating element configured to adjust an amount of air transferred from the at least one cabinet to the at least one first air channel and to adjust an amount of air circulated through the at least one cabinet within the interior chamber.

An exemplary embodiment of the present disclosure provides an enclosure which includes a bottom part, a wall part and a roof part, which define an interior chamber for housing electrical equipment. The wall part includes at least one first air channel connected to the interior chamber, and the bottom part includes at least one second air channel connected to the interior chamber. The exemplary enclosure also includes at least one first fan configured to circulate air from inside the interior chamber through the at least one first air channel. The at least one fan may be configured to circulate the air from inside the interior chamber through the at least one second air channel. In addition, the exemplary enclosure includes at least one cabinet, inside the interior chamber, for the electrical equipment. The at least one first air channel is connected to the at least one cabinet such that the air circulated from inside the interior chamber through the at least one first air channel enters the at least one first air channel through the at least one cabinet. The exemplary enclosure also includes a regulator in a point of connection between the at least one first air channel and the at least one cabinet. The regulator is configured to adjust an amount of air transferred from the at least one cabinet to the at least one first air channel and to adjust an amount of air circulated through the at least one cabinet within the interior chamber.

### BRIEF DESCRIPTION OF THE DRAWINGS

Additional refinements, advantages and features of the present disclosure are described in more detail below with reference to exemplary embodiments illustrated in the drawings, in which:

FIG. 1 shows an enclosure according to an exemplary embodiment of the present disclosure;

FIG. 2 shows a part of a cross-section of the enclosure according to an exemplary embodiment of the present disclosure; and

FIG. 3 shows a cross section of a wall part of the enclosure according to an exemplary embodiment of the present disclosure.

### DETAILED DESCRIPTION

Exemplary embodiments of the present disclosure provide an enclosure for housing electrical equipment which solves or at least alleviates the drawbacks noted above. An exemplary embodiment of the present disclosure provides an enclosure for housing electrical equipment. The exemplary enclosure includes a bottom part, a wall part, and a roof part. The bottom part, the wall part and the roof part define an interior chamber for housing the electrical equipment. The wall part includes at least one first air channel connected to the interior chamber. The bottom part includes at least one second air channel connected to the interior chamber. The enclosure also includes at least one fan configured to circulate air from inside the interior chamber through the at least one first air channel, and the at least one fan configured to circulate the air from inside the interior chamber through the at least one second air channel. In addition, the exemplary enclosure includes, inside the interior chamber, at least one cabinet for the electrical equipment. The at least one first air channel is connected to the at least one cabinet at a connection point such that the air circulated from inside the interior chamber through the at least one first air channel enters the at least one first air channel through the at least one cabinet. The connection point of the at least one first air channel and the at least one cabinet includes a first regulating element configured to adjust an amount of air transferred from the at least one cabinet to the at least one first air channel and to adjust an amount of air circulated through the at least one cabinet within the interior chamber.

Another exemplary embodiment of the present disclosure provides an enclosure which includes a bottom part, a wall part and a roof part, which define an interior chamber for housing electrical equipment. The wall part includes at least one first air channel connected to the interior chamber, and the bottom part includes at least one second air channel connected to the interior chamber. The exemplary enclosure also includes at least one fan configured to circulate air from inside the interior chamber through the at least one first air channel, and the at least one fan configured to circulate the air from inside the interior chamber through the at least one second air channel. In addition, the exemplary enclosure includes at least one cabinet, inside the interior chamber, for the electrical equipment. The at least one first air channel is connected to the at least one cabinet such that the air circulated from inside the interior chamber through the at least one first air channel enters the at least one first air channel through the at least one cabinet. The exemplary enclosure also includes a regulator in a point of connection between the at least one first air channel and the at least one cabinet. The regulator is configured to adjust an amount of air transferred from the at least one cabinet to the at least one first air channel and to adjust an amount of air circulated through the at least one cabinet within the interior chamber.

Additional features of exemplary embodiments of the present disclosure are described in more detail below with reference to the drawings.

Exemplary embodiments of the present disclosure are based on the idea that, in addition to a wall part of an enclosure for housing electrical equipment including at least one first air channel connected to the interior chamber and the enclosure including at least one fan for circulating air from inside an interior chamber of the enclosure through the at least one first air channel, a bottom part of the enclosure for housing the electrical equipment includes at least one second air channel connected to the interior chamber, and the enclosure includes at least one fan for circulating the air from inside the interior chamber through the at least one second air channel.

According to this arrangement, the heat regulation of the enclosure can be enhanced because the heat capacity of the bottom part of the enclosure and the soil can be utilized in reducing temperature variation inside the enclosure due to varying loss heat power. This arrangement is advantageous, for example, in connection with systems operating in cycles, such as solar power systems, in which the cycle of power dissipation naturally has a length of one day. This further facilitates the optimization of the equipment and the structures.

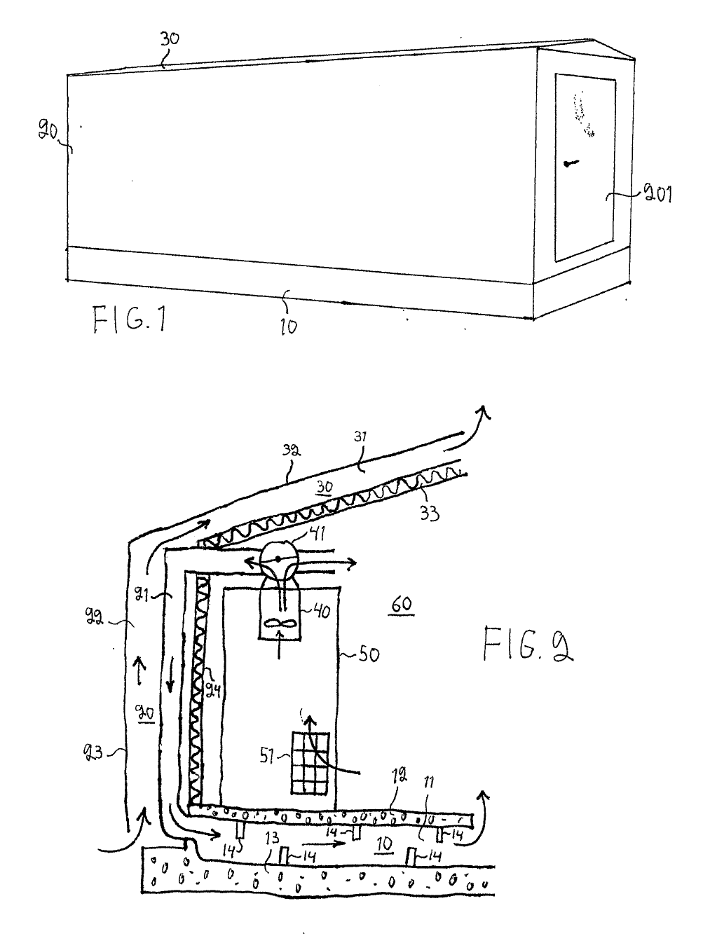

FIG. 1 shows an enclosure according to an exemplary embodiment of the present disclosure. It should be noted that the shape and size of the enclosure may vary. The enclosure may be used for housing electrical equipment, such as electrical power equipment and/or electronic equipment or other electrical equipment, for example. The enclosure includes a bottom part 10, a wall part 20 and a roof part 30. The bottom part 10, the wall part 20 and the roof 30 part define an interior chamber for housing the electrical equipment. The bottom part 10 may be made of, for example, concrete or some other material and can be of a single-piece or a multi-piece construction. The wall part 20 may include one or more wall elements, for example, four wall elements as shown in FIG. 1. At least one of the wall elements may include at least one door 201 providing access to the interior chamber and the equipment located there.

FIG. 2 shows a part of a cross-section of the enclosure according to an exemplary embodiment of the present disclosure. The wall part 20 includes at least one first air channel 21 connected to the interior chamber 60, and the enclosure includes at least one fan 40 for circulating air from inside the interior chamber 60 through the at least one first air channel 21. The at least one first air channel 21 may be located between an interior wall structure 24 and an exterior wall structure 23 within the wall part 20, for example. The interior wall structure 24 may be thermally insulated. The air circulated through the at least one first air channel 21 releases part of its heat energy through the wall structures to the air outside the enclosure and thus the air circulated through the at least one first air channel 21 cools down. The material of the at least one first air channel 21 may be heat conductive, such as aluminium, for example, in order to ensure proper heat conduction. Moreover, the bottom part 10 includes at least one second air channel 11 connected to the interior chamber 60, and the enclosure includes at least one fan 40 for circulating the air from inside the interior chamber 60 through the at least one second air channel 11. The at least one second air channel 11 may be located between an inner floor structure 12 and a base floor structure 13, for example. The air circulated through the at least one second air channel 11 releases or receives heat energy to/from the floor structure. In addition, since the bottom part 10 may lie against the soil when the enclosure has been assembled into use and heat exchange thus takes place between the bottom part 10 and the soil, also the heat capacity of the soil below the enclosure can be utilized. The temperature of the soil at a depth of approximately two meters settles around the yearly average temperature of the outside air and thus the soil can function as an effective heat sink.

In the example of FIG. 1, the at least one first air channel 21 and the at least one second air channel 11 are connected in series, and the same fan 40 is used to circulate air from inside the interior chamber 60 through the at least one first air channel 21 and also through the at least one second air channel 11. However, the at least one first air channel 21 and the at least one second air channel 11 need not be connected in series but may be separately connected to the interior chamber 60 and separate fans could be used for both the channels. The interior chamber 60, the at least one first air channel 21 and the at least one second air channel 11 may be substantially sealed from outside of the enclosure. In other words, the interior chamber 60, the at least one first air channel 21 and the at least one second air channel 11 form a substantially closed environment inside the enclosure.

As shown in the example of FIG. 2, the enclosure may include at least one cabinet 50 for electrical equipment inside the interior chamber 60, wherein the at least one first air channel 21 may be connected to the at least one cabinet 50 such that the air circulated from inside the interior chamber 60 through the at least one first air channel 21 enters the at least one first air channel 21 through the at least one cabinet 50. The at least one cabinet 50 may have suitable openings 51 for enabling the flow of air through it. This enhances the cooling of the equipment inside the cabinet 50. Moreover, the point of connection between the at least one first air channel 21 and the at least one cabinet 50 may include a first regulating element 41 for adjusting an amount of air transferred from the at least one cabinet 50 to the at least one first air channel 21 and for adjusting an amount of air circulated through the at least one cabinet 50 within the interior chamber 60. The first regulating element 41 may be combined with the fan 40, or they may be separate elements. The first regulating element 41 thus adjusts which portion of air circulated through the at least one cabinet 50, on one hand, enters the at least one first air channel 21 and which portion of air circulated through the at least one cabinet 50, on the other hand, exits the at least one cabinet 50 yet stays within the interior chamber 60. The flow of air has been shown with arrows in FIG. 2. Thus, the first regulating element 41 may be used for adjusting the temperature inside the enclosure.

In case the at least one first air channel 21 and the at least one second air channel 11 are connected in series as in the example of FIG. 2, the point of connection between the at least one first air channel 21 and the at least one second air channel 11 may include a second regulating element for adjusting an amount of air transferred between the at least one first air channel 21 and the at least one second air channel 11 and for adjusting an amount of air released back to the interior chamber 60 from the connection point between the at least one first air channel 21 and the at least one second air channel 11. In this way, the flow of air through the at least one first air channel 21 and the one through the at least one second air channel 11 could be adjusted individually.

According to an exemplary embodiment, the wall part 20 may include at least one third air channel 22 connected to the outside of the enclosure, in which case the at least one first air channel 21 and the at least one third air channel 22 may form a heat exchanger. The at least one first air channel 21 and the at least one third air channel 22 may be run side by side inside the wall part 20 to ensure proper heat exchange between them. The air may be circulated generally downwards inside the at least one first air channel 21 and generally upwards inside the at least one third air channel 22. The enclosure may include at least one fan for circulating air from outside of the enclosure through the at least one third air channel 22. Such a fan may be located at either end of the air channel, for example. Alternatively, the air from the outside of the enclosure may circulate through the at least one third air channel 22 by natural convection caused by the fact that warm air tends to move upwards. This natural convection may be enhanced by continuing the at least one third air channel 22 with at least one fourth air channel 31 through the roof part 30, thus utilizing the air flow warming effect of the sun shining to the roof 30. Within the roof part 30 the at least one fourth air channel 31 may be located between an interior roof structure 33 and an exterior roof structure 32, for example. The interior roof structure 33 may be thermally insulated. The natural air flow through the at least one third air channel 22 and/or at least one fourth air channel 31 may be further enhanced by using suitable materials or coatings, for example, as follows:

1) The emissivity of an exterior surface of the exterior wall structure 23 against direct radiation from the sun may be as low as possible, for example, generally low against heat radiation from the outside of the enclosure. The emissivity of the exterior wall structure 23 against low temperature radiation between surfaces may also be as low as possible. This allows the heating effect of direct radiation from the sun to the wall structure to be minimized. On the other hand, the interior wall structures may have high low-temperature emissivities as heat exchange in the interior wall structures is desired.

2) In the roof structure, the heating effect of the sun on the air flow channel 31 is desirable and thus an exterior surface of the exterior roof structure 32 may have a high high-temperature emissivity, for example, a high emissivity against heat radiation from the outside of the enclosure, but a low low-temperature emissivity and the inside surfaces of the channel 31 may have high low-temperature emissivities.

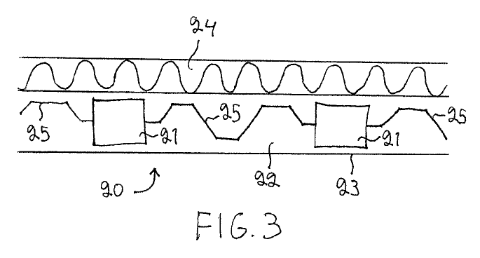

FIG. 3 shows a cross section of the wall part 20 of the enclosure according to an exemplary embodiment of the present disclosure. According to the illustrated embodiment, the wall part includes at least one rib 25 attached to the at least one first air channel 21, where the rib 25 extends to the at least one third air channel 22. The purpose of the at least one rib 25 is to enhance heat exchange between the at least one first air channel 21 and the at least one third air channel 22. The at least one rib 25 may be straight or corrugated, as shown in FIG. 3, to enlarge the heat exchanging surface area and thus further enhance heat exchange between the air flowing inside the at least one first air channel 21 and the air flowing inside the at least one third air channel 22. The material of the at least one rib 25 may be heat conductive, such as aluminium, in order to ensure proper heat conduction, for example.

According to an exemplary embodiment, the bottom part 10 includes one or more ribs 14 extending inside the at least one second air channel 11. Such ribs 14 may be used to further enhance heat exchange between the air circulated through the at least one second air channel 11 and the floor structure. The one or more ribs 14 extending inside the at least one second air channel 11 may be integral parts of the bottom part 10 or separate parts attached to, for example, the inner floor structure 12 and the base floor structure 13. The shape and size of the at least one rib 14 extending inside the at least one second air channel 11 may vary from that shown in the example of FIG. 2.

The air flow through the at least one first air channel 21 and the at least one second air channel 11 may be controlled according to at least one of the following: temperature inside the enclosure, temperature outside the enclosure, time of day, and temperature of the bottom part 10. Also, other parameters may be used. As an example, the control of the air flow may be implemented such that the thermal energy stored in the bottom part 10 is maximized. Generally the bottom part 10 of the enclosure may be used to even out the daily variation of temperature inside the enclosure caused by the dissipation power of the electrical equipment, on one hand, by storing thermal energy from the air flow inside the at least one second air channel 11 to the bottom part 10 and, on the other hand, by releasing thermal energy from the bottom part 10 to the air flow inside the at least one second air channel 11. A bottom part made of, for example, concrete or a similar material may store the thermal power peak occurring around noon and the stored thermal energy may then be transferred to the outside air during night-time. The control according to the various embodiments described above may be implemented by controlling the operation of the fan(s) 40 and the regulating element(s) 41. The operation of the fan(s) 40 and the regulating element(s) 41 may be controlled by one or more control units, which may be integrated into the fan(s) 40 and the regulating element(s) 41 or they may be separate elements within the enclosure or possibly at a remote location. Such a control unit may be implemented by means of a computer or corresponding digital signal processing equipment having a processor configured to execute suitable software tangibly recorded on a non-transitory computer-readable recording medium, such as a ROM, hard disk drive or other non-volatile memory, for example. The control unit may include suitable input means for receiving, for example, measurement and/or control data and output means for outputting control data.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

What is claimed is:

1. An enclosure for housing electrical equipment, the enclosure comprising:
a bottom part;
a wall part; and
a roof part, wherein:
the bottom part, the wall part and the roof part define an interior chamber for housing the electrical equipment;
the wall part includes at least one first air channel connected to the interior chamber;
the bottom part includes at least one second air channel connected to the interior chamber;
the enclosure comprises at least one fan configured to circulate air from inside the interior chamber through the at least one first air channel;
the enclosure comprises at least one fan configured to circulate the air from inside the interior chamber through the at least one second air channel;
the enclosure comprises, inside the interior chamber, at least one cabinet for the electrical equipment;
the at least one first air channel is connected to the at least one cabinet at a connection point such that the air circulated from inside the interior chamber through the at least one first air channel enters the at least one first air channel through the at least one cabinet; and
the connection point of the at least one first air channel and the at least one cabinet includes a first regulating element configured to adjust an amount of air transferred from the at least one cabinet to the at least one first air channel and to adjust an amount of air circulated through the at least one cabinet within the interior chamber.

2. The enclosure of claim 1, wherein the interior chamber, the at least one first air channel and the at least one second air channel are substantially sealed from the outside of the enclosure.

3. The enclosure of claim 1, wherein the at least one first air channel and the at least one second air channel are connected in series.

4. The enclosure of claim 3, wherein a connection point of the at least one first air channel and the at least one second air channel includes a second regulating element configured to adjust an amount of air transferred between the at least one first air channel and the at least one second air channel and to adjust an amount of air released back to the interior chamber from the connection point of the at least one first air channel and the at least one second air channel.

5. The enclosure of claim 1, wherein the wall part includes at least one third air channel connected to the outside of the enclosure, wherein the at least one first air channel and the at least one third air channel form a heat exchanger.

6. The enclosure of claim 5, wherein an emissivity of an exterior surface of an exterior wall part structure against heat radiation from the outside of the enclosure is low.

7. The enclosure of claim 5, wherein the roof part includes at least one fourth air channel connected to the at least one third air channel.

8. The enclosure of claim 7, wherein an emissivity of an exterior surface of an exterior roof part structure against heat radiation from the outside of the enclosure is high.

9. The enclosure of claim 5, comprising:
at least one fan configured to circulate air from the outside of the enclosure through the at least one third air channel.

10. The enclosure of claim 1, wherein the wall part includes at least one rib attached to the at least one first air channel, the at least one rib extending to the at least one third air channel.

11. The enclosure of claim 1, wherein the bottom part includes at least one rib extending inside the at least one second air channel.

12. The enclosure of claim 1, wherein the wall part includes one or more wall elements.

13. The enclosure of claim 12, wherein at least one of the one or more wall elements includes a door.

14. The enclosure of claim 1, wherein the at least one fan configured to circulate air from inside the interior chamber through the at least one first air channel is a different fan from the at least one fan configured to circulate the air from inside the interior chamber through the at least one second air channel.

15. The enclosure of claim 5, wherein the at least one fan configured to circulate air from inside the interior chamber through the at least one first air channel is the same fan as the at least one fan configured to circulate the air from inside the interior chamber through the at least one second air channel.

16. An enclosure comprising:
a bottom part, a wall part and a roof part, which define an interior chamber for housing electrical equipment, wherein the wall part includes at least one first air channel connected to the interior chamber, and the bottom part includes at least one second air channel connected to the interior chamber;
at least one fan configured to circulate air from inside the interior chamber through the at least one first air channel;
at least one fan configured to circulate the air from inside the interior chamber through the at least one second air channel;
at least one cabinet, inside the interior chamber, for the electrical equipment, wherein the at least one first air channel is connected to the at least one cabinet such that the air circulated from inside the interior chamber through the at least one first air channel enters the at least one first air channel through the at least one cabinet; and
a regulator in a point of connection between the at least one first air channel and the at least one cabinet, the regulator being configured to adjust an amount of air transferred from the at least one cabinet to the at least one first air channel and to adjust an amount of air circulated through the at least one cabinet within the interior chamber.

17. The enclosure of claim 16, wherein the at least one fan configured to circulate air from inside the interior chamber through the at least one first air channel is a different fan from the at least one fan configured to circulate the air from inside the interior chamber through the at least one second air channel.

18. The enclosure of claim 16, wherein the at least one fan configured to circulate air from inside the interior chamber through the at least one first air channel is the same fan as the at least one fan configured to circulate the air from inside the interior chamber through the at least one second air channel.
